(19) United States
(12) Patent Application Publication
(10) Pub. No.: US 2019/0393030 A1
(43) Pub. Date: Dec. 26, 2019

(54) Carbon Gapfill Films

(71) Applicant: Applied Materials, Inc., Santa Clara, CA (US)

(72) Inventors: Shishi Jiang, Santa Clara, CA (US); Eswaranand Venkatasubramanian, Santa Clara, CA (US); Pramit Manna, Sunnyvale, CA (US); Abhijit Basu Mallick, Palo Alto, CA (US)

(21) Appl. No.: 16/445,659

(22) Filed: Jun. 19, 2019

Related U.S. Application Data
(60) Provisional application No. 62/687,453, filed on Jun. 20, 2018.

(51) Int. Cl. H01L 21/02; C23C 16/56; C23C 16/50; C23C 16/46

(52) U.S. Cl. CPC H01L 21/02274; H01L 21/02205; C23C 16/46; C23C 16/56; C23C 16/50; H01L 21/02115

(57) ABSTRACT

Methods are described for forming flowable carbon layers on a semiconductor substrate. A local excitation (such as a plasma in PECVD) may be applied as described herein to a carbon-containing precursor to form a flowable carbon film on a substrate. A remote excitation method has also been found to produce flowable carbon films by exciting a stable precursor to produce a radical precursor which is then combined with an unexcited carbon-containing precursor in the substrate processing region. An optional post deposition plasma exposure may also cure or solidify the flowable film after deposition. Methods for forming air gaps using the flowable films described herein are also described.

### CROSS-REFERENCE TO RELATED APPLICATIONS

This application claims priority to U.S. Provisional Application No. 62/687,453, filed Jun. 20, 2018, the entire disclosure of which is hereby incorporated by reference herein.

### FIELD

The present disclosure relates generally to methods of depositing thin films. In particular, the disclosure relates to processes for filling narrow trenches with flowable carbon films and optionally curing the flowable films.

### BACKGROUND

The miniaturization of semiconductor circuit elements has reached a point where feature sizes of 45 nm, 32 nm, 28 nm and even 20 nm are fabricated on a commercial scale. As the dimensions continue to get smaller, new challenges arise for process steps like filling a gap between circuit elements with a variety of materials. As the width between the elements continues to shrink, the gap between them often gets taller and narrower, making the gap more difficult to fill without the gapfill material getting stuck to create voids and weak seams. Conventional chemical vapor deposition (CVD) techniques often experience an overgrowth of material at the top of the gap before it has been completely filled. This can create a void or seam in the gap where the depositing material has been prematurely cut off by the overgrowth; a problem sometimes referred to as breadloafing.

One solution to the breadloafing problem has been to use a gapfill precursor and a plasma-excited precursor combined in a plasma-free substrate processing region to form a nascently-flowable film. The as-deposited flowability allows the film to fill gaps without a seam or void using this chemical vapor deposition technique. Such a chemical vapor deposition has been found to produce better gapfill properties than spin-on glass (SOG) or spin-on dielectric (SOD) processes. While the deposition of flowable films deposited by CVD has fewer breadloafing problems, such techniques are still unavailable for some classes of material.

While flowable CVD techniques represent a significant breakthrough in filling tall, narrow (i.e., high-aspect ratio) gaps with other gapfill materials, there is still a need for techniques that can seamlessly fill such gaps with highly pure carbon-based materials. Previous carbon-based gapfill films have contained a significant amount of oxygen and silicon. These elements significantly alter the properties of the carbon-based gapfill films.

Therefore, there is a need for precursors and methods for depositing carbon gapfill films without oxygen or silicon.

### SUMMARY

One or more embodiments of this disclosure are directed to a flowable carbon film deposition method. The method comprises providing a substrate to a substrate processing region of a processing chamber. A reactive plasma comprising a carbon-containing precursor is formed. The carbon-containing precursor comprises substantially no oxygen. The reactive plasma comprises substantially no oxygen. The substrate is exposed to the reactive plasma to deposit a flowable carbon film on the substrate. The flowable carbon film comprises substantially no silicon nor oxygen.

Additional embodiments of this disclosure are directed to a flowable carbon film deposition method. The method comprises providing a substrate to a substrate processing region of a processing chamber. The substrate has a substrate surface with at least one feature thereon. The at least one feature extends a depth from the substrate surface to a bottom surface. The at least one feature has an opening width at the substrate surface defined by a first sidewall and a second sidewall. The at least one feature has a ratio of the depth to the opening width of greater than or equal to about 10:1. A first plasma is formed within the substrate processing region. The first plasma comprises a carbon-containing precursor and a first plasma gas. The carbon-containing precursor comprises substantially no oxygen, and the first plasma comprises substantially no oxygen. The substrate is exposed to the first plasma to deposit a flowable carbon film in the at least one feature. The flowable carbon film deposited in the at least one feature has substantially no seam, and the flowable carbon film comprises substantially no silicon nor oxygen. The flowable carbon film is exposed to a second plasma to cure the flowable carbon film. The second plasma is produced by exciting a second plasma gas. The method is performed in a single chamber without breaking vacuum. The substrate is maintained at about the same temperature throughout the method.

Further embodiments of this disclosure are directed to a method of forming an air gap in a substrate feature. The method comprises providing a substrate to a substrate processing region of a processing chamber. The substrate has a substrate surface with at least one feature thereon. The at least one feature extends a depth from the substrate surface to a bottom surface. The at least one feature has an opening width at the substrate surface defined by a first sidewall and a second sidewall. The at least one feature has a ratio of the depth to the opening width of greater than or equal to about 10:1. A flowable carbon film is deposited in a first portion of the at least one feature. The flowable carbon film is deposited by a process that comprises exciting a carbon-containing precursor to form a plasma. The carbon-containing precursor comprises substantially no oxygen. The plasma comprises substantially no oxygen. The substrate is exposed to the plasma to deposit a flowable carbon film in the at least one feature. The flowable carbon film is deposited in the at least one feature has substantially no seam and the flowable carbon film comprises substantially no silicon nor oxygen. A material is deposited on the flowable carbon film in a second portion of the at least one feature. The flowable carbon film is removed from the first portion of the at least one feature to form an air gap in the first portion of the at least one feature.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flowchart illustrating selected steps in a method of forming a flowable carbon layer on a substrate;

FIG. 2 shows a substrate processing system according to some embodiments of the disclosure;

FIG. 3A shows a substrate processing chamber according to some embodiments of the disclosure; and

FIG. 3B shows a gas distribution showerhead according to some embodiments of the disclosure.

### DETAILED DESCRIPTION

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Embodiments of this disclosure relate to methods for forming flowable carbon layers on a semiconductor substrate and optionally curing or solidifying the flowable carbon layers. As used throughout this disclosure and the appended claims, a carbon layer and a carbon film should be understood as referring to the same material. A reactive plasma may be formed, as described further herein, from a carbon-containing precursor comprising substantially no oxygen atoms to form a flowable carbon film on a substrate. A remote excitation method has also been found to produce flowable carbon films by exciting a stable precursor to produce a radical precursor which is then combined with unexcited carbon-containing precursor to form a reactive plasma in the substrate processing region.

In the case of a local excitation, a local plasma may be used to excite the carbon-containing precursor. The inventors have determined that these techniques can be modified to form a flowable carbon film on a substrate in the same substrate processing region housing the excitation region. In some embodiments, the process allows for adequate recombination and de-excitation of the precursor before the precursors travel to the substrate. The recombination and de-excitation removes ionized species from the reactant flow and enables the nascent film to flow prior to solidification or curing. The flowrates, precursors and process parameters presented in the ensuing discussion apply to both the local and remote plasma techniques.

In an exemplary remote plasma CVD process, the carbon constituents of the flowable carbon film may come from a carbon-containing precursor which is excited by a radical precursor formed in a remote plasma formed outside the substrate processing region. The radical precursor may be formed from ammonia, argon, hydrogen, helium or the like. The radical precursor comprises substantially no oxygen atoms. As both the carbon-containing precursor and the stable precursor/radical precursor comprise substantially no oxygen atoms, the reactive plasma comprises substantially no oxygen atoms. The remote plasma may be a remote plasma system or a compartment within the same substrate processing system but separated from the substrate processing region by a showerhead. The radical precursor is activated, in part, to form a flowable carbon film when combined the carbon-containing precursor at low deposition temperatures. In those parts of the substrate that are structured with high-aspect ratio gaps, the flowable carbon material may be deposited into those gaps with substantially no seam.

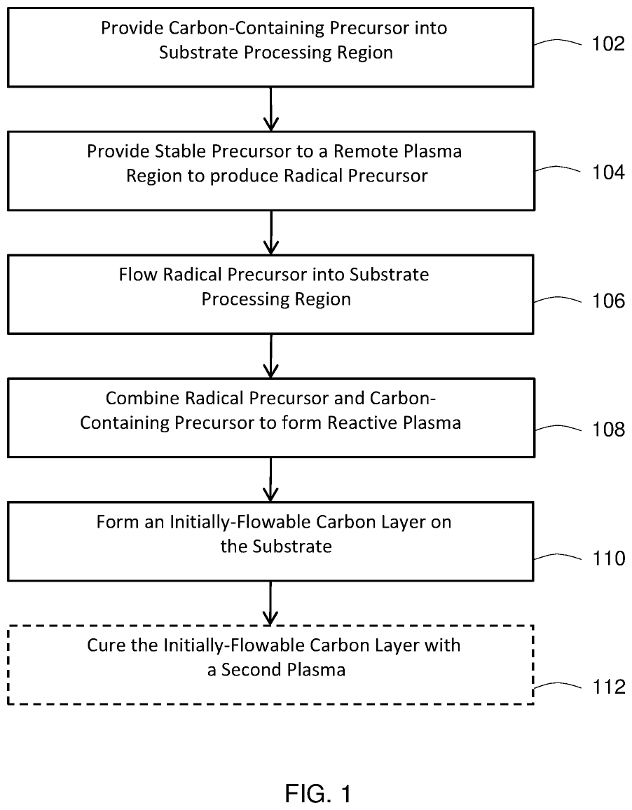

In order to better understand and appreciate the invention, reference is now made to FIG. 1 which is a flowchart showing selected steps in a method of forming a flowable carbon layer on a substrate according to embodiments of the invention. The method includes the step of providing a carbon-containing precursor 102 to a substrate processing region of a chemical vapor deposition chamber. The carbon-containing precursor provides the carbon used in forming a flowable carbon layer.

Carbon-containing precursors include hydrocarbons and consist of hydrocarbons in embodiments of the invention. The carbon-containing precursor consists of carbon, hydrogen and optionally nitrogen. The carbon-containing precursor has no oxygen nor fluorine (or other halogen atoms) in disclosed embodiments. Exemplary carbon-containing precursors include alkanes, alkenes, alkynes, amines, imines and nitriles.

Exemplary carbon-containing precursors include methane, ethane, ethylene, acetylene, propane, propene, propyne, butane, butene, butyne, hexane, hexene, hexyne, heptane, heptene, heptyne, octane, octene, octyne, and longer chain hydrocarbons among others. The carbon-containing precursor may be a cyclic hydrocarbon including but not limited to cyclopropane, cyclohexane, cyclohexene, or cycloheptane. The carbon-containing precursor may be an aromatic hydrocarbon. Exemplary carbon-containing precursors may include benzene, toluene, xylene, mesitylene, aniline and pyridine. In some embodiments, the carbon-containing precursor consists essentially of propene, acetylene or methane.

Generally speaking, the carbon-containing precursor may include carbon and hydrogen, but may also include nitrogen. In particular embodiments, the reactive component of the carbon-containing precursor consists essentially of carbon and hydrogen. As used in this manner, the term “consists essentially of” means that the composition of the subject reactive gas is greater than or equal to about 95%, 98%, 99% or 99.5% of the stated elements (in sum) on an atomic basis. The carbon-containing precursor may consist of carbon, hydrogen and nitrogen. In some embodiments, the carbon-containing precursor comprises four to twelve, four to ten, four to eight, six to twelve, six to ten, eight to twelve or greater than or equal to four, six, eight, or twelve carbon atoms.

In some embodiments, the carbon-containing precursor comprises at least one unsaturated bond. In some embodiments, the unsaturated bond is a carbon-carbon unsaturated bond. In some embodiments, the unsaturated bond is a carbon-nitrogen unsaturated bond. In some embodiments, the carbon-containing precursor comprises a vinyl functional group. In some embodiments, the carbon-containing precursor is selected from the group consisting of ethene, propene, isobutylene, butadiene, and styrene. In some embodiments, the unsaturated bond is a terminal unsaturated bond. In some embodiments, the carbon-containing precursor comprises a ring structure, either aromatic or non-aromatic.

A stable precursor is flowed into a remote plasma region (operation 104) to produce a radical precursor. The radical precursor was flowed into the substrate processing region through a showerhead (operation 106), where the radical precursor combines with the carbon-containing precursor (operation 108) to form a reactive plasma. The carbon-containing precursor has not been flowed through a plasma and is only excited by the radical precursor. The unexcited carbon-containing precursor and the radical precursor have been found to combine in such a way as to form a flowable carbon layer (operation 110).

In general, the stable precursor may include any suitable gas which contains no oxygen nor silicon. Exemplary stable precursors include noble gases (e.g., Ne, Kr, Ar, Xe, He), NH₃, and H₂. The flow rate of the stable precursor (and therefore the radical precursor) may be greater than or about 300 sccm, greater than or about 500 sccm or greater than or about 700 sccm in disclosed embodiments. The flow rate of the carbon-containing precursor may be greater than or about 100 sccm, greater than or about 200 sccm, greater than or about 250 sccm, greater than or about 275 sccm, greater than or about 300 sccm, greater than or about 350 sccm, greater than or about 400 sccm, etc. or more in disclosed embodiments.

The semiconductor substrate used for forming and depositing the flowable carbon layer may be a patterned semiconductor substrate and may have a plurality of gaps or features for the spacing and structure of device components (e.g., transistors) formed on the semiconductor substrate. The gaps may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths of that range from about 90 nm to about 22 nm or less (e.g., less than 90 nm, 65 nm, 50 nm, 45 nm, 32 nm, 22 nm, 16 nm, etc.). Because the carbon layer is initially flowable, it can fill gaps with high aspect ratios without creating voids or weak seams around the center of the filling material. For example, a depositing flowable material is less likely to prematurely “clog” or cover the top of a gap before it is completely filled to leave a void or seam in the middle of the gap.

The substrate has a top surface. The at least one feature forms an opening in the top surface. The feature extends from the top surface a depth to a bottom surface. The feature has a first sidewall and a second sidewall that define an opening width of the feature. The open area formed by the sidewalls and bottom is also referred to as a gap.

In specific embodiments, the feature is a trench. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

Measured by atomic concentration, the carbon layer may contain at least 70% carbon, at least 75% carbon, at least 80% carbon and at least 85% carbon in embodiments of the invention. Generally speaking, the carbon layer may include carbon and hydrogen, but may also include nitrogen or other elements. The carbon layer comprises substantially no silicon nor oxygen. In particular embodiments, the silicon-free carbon-containing layer may consist of carbon and hydrogen. The carbon layer may consist of carbon, hydrogen and nitrogen.

The stable precursor may be energized by a plasma formed in a remote plasma system (RPS) positioned outside or inside the deposition chamber in order to form the radical precursor. The stable precursor may be exposed to the remote plasma where it is dissociated, radicalized, and/or otherwise transformed into the plasma effluents also known as the radical precursor. The radical precursor is then introduced to the substrate processing region to mix for the first time with the separately introduced carbon-containing precursor to form a reactive plasma. Exciting the carbon-containing precursor by contact with the radical precursor, rather than directly by a plasma, forms unique deposition intermediaries. These intermediaries would not be present if a plasma were to directly excite the carbon-containing precursor. These deposition intermediaries may contain longer carbon chains which enable the carbon layer to initially be flowable unlike conventional carbon layer deposition techniques. The flowable nature during formation allows the layer to flow into narrow features before being solidified or cured.

Alternatively (or in addition) to an exterior plasma region, the stable precursor may be excited in a plasma region inside the deposition chamber. This plasma region may be partitioned from the substrate processing region. The precursors mix and react in the substrate processing region to deposit the flowable carbon layer on the exposed surfaces of the substrate. Regardless of the location of the plasma region, the substrate processing region may be described as a “plasma free” region during the deposition process. It should be noted that “plasma free” does not necessarily mean the region is devoid of plasma. The borders of the plasma in the chamber plasma region are hard to define and may encroach upon the substrate processing region through, for example, the apertures of a showerhead if one is being used to transport the precursors to the substrate processing region. If an inductively-coupled plasma is incorporated into the deposition chamber, a small amount of ionization may even be initiated in the substrate processing region during a deposition without deviating from the scope of the present invention. All causes for a plasma having much lower ion density than the chamber plasma region during the creation of the radical precursor do not deviate from the scope of “plasma-free” as used herein.

The carbon layer is formed on the substrate and is initially flowable during deposition. The origin of the flowability may be linked to the presence of hydrogen in the film, in addition to carbon. The hydrogen is thought to reside as C—H bonds in the film which may aid in the initial flowability. The temperature in the reaction region of the substrate processing region may be low (e.g., less than 100° C.) and the total chamber pressure may be about 0.1 Torr to about 10 Torr (e.g., about 1 to about 10 Torr, etc.) during the deposition of the carbon layer. The temperature may be controlled in part by a temperature controlled pedestal that supports the substrate. The pedestal may be thermally coupled to a cooling/heating unit that adjust the pedestal and substrate temperature to, for example, about −100° C. to about 100° C. The flowability does not rely on a high substrate temperature; therefore, the initially-flowable carbon layer may fill gaps even on relatively low temperature substrates. During the formation of the carbon layer, the substrate temperature may be below or about 100° C., below or about 50° C., below or about 25° C., or below or about 0° C.

The initially flowable carbon layer may be deposited on exposed planar surfaces a well as into gaps. As measured on an open area on the patterned substrate, the deposition thickness may be about 50 Å or more, about 100 Å or more, about 150 Å or more, about 200 Å or more, about 300 Å or more, or about 400 Å, in disclosed embodiments. The deposition thickness may be about 2000 Å or less, about 1500 Å or less, about 1000 Å or less, about 800 Å or less, about 600 Å or less, or about 500 Å, in embodiments of the invention. Additional disclosed embodiments may be obtained by combining one of these upper limits with one of the lower limits.

When the flowable carbon layer reaches a desired thickness, the process effluents may be removed from the deposition chamber. These process effluents may include any unreacted radical precursor and carbon-containing precursor, diluent and/or carrier gases, and reaction products that did not deposit on the substrate. The process effluents may be removed by evacuating the deposition chamber and/or displacing the effluents with non-deposition gases in the deposition region.

As indicated previously, a local excitation may be used in place of a remote plasma excitation. A local plasma may also be used to excite the carbon-containing precursor. PE-CVD may also be used to form the flowable carbon film by reducing the local plasma intensity to below about 100 Watts, below about 50 Watts, below about 40 Watts, below about 30 Watts or below about 20 Watts in disclosed embodiments. In some embodiments, the local plasma may be greater than 3 Watts or greater than 5 Watts. Any of the upper bounds can be combined with any of the lower bounds to form additional embodiments. The plasma may be effected by applying RF energy by capacitively-coupled power between, e.g., the gas distribution showerhead and the pedestal/substrate. Such low powers are typically not used in prior art systems as a result of plasma instability and previously undesirably low film growth rates. Low substrate temperatures (as outlined previously) are required in all embodiments described herein in order to form flowable carbon films. Higher process pressures also help de-excitation and promote a flowable film and the substrate processing region may be maintained at a pressure between 0.1 Torr and 10 Torr in embodiments of the invention. For PE-CVD, the separation between a gas supply showerhead may be increased to spacing deemed undesirable for prior art processes. Greater gas supply to substrate face spacings of greater than or equal to about 300 mil, about 400 mil, about 500 mil, about 750 mil, about 1000 mil, about 1500 mil, about 2000 mil, about 5000 mil, about 7500 mil, about 10000 mil or about 12000 mil have been found to produce flowable carbon films in disclosed embodiments.

Additional process parameters will be introduced in the course of describing some exemplary hardware. Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers.

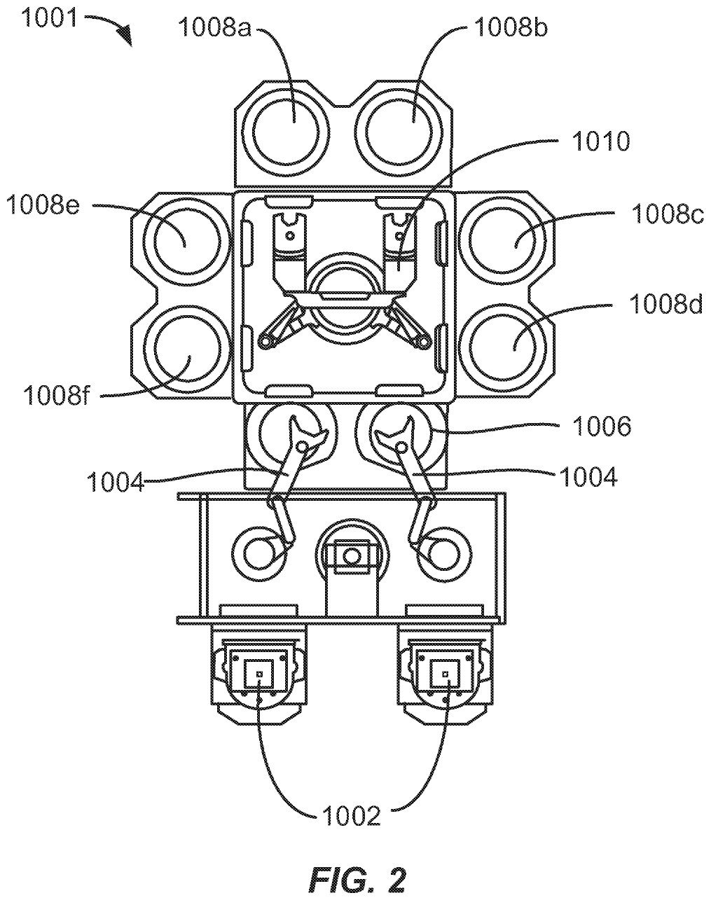

Embodiments of the deposition systems may be incorporated into larger fabrication systems for producing integrated circuit chips. FIG. 2 shows one such system 1001 of deposition and other processing chambers according to disclosed embodiments. In the figure, a pair of FOUPs (front opening unified pods) 1002 supply substrate substrates (e.g., 300 mm diameter wafers) that are received by robotic arms 1004 and placed into a low pressure holding area 1006 before being placed into one of the wafer processing chambers 1008a-f. A second robotic arm 1010 may be used to transport the substrate wafers from the holding area 1006 to the processing chambers 1008a-f and back. The processing chambers 1008a-f may include one or more system components for depositing a flowable dielectric film on the substrate wafer. In one configuration, all three pairs of chambers (e.g., 1008a-f) may be configured to deposit a flowable dielectric film on the substrate. Any one or more of the processes described may be carried out on chamber(s) separated from the fabrication system shown in different embodiments.

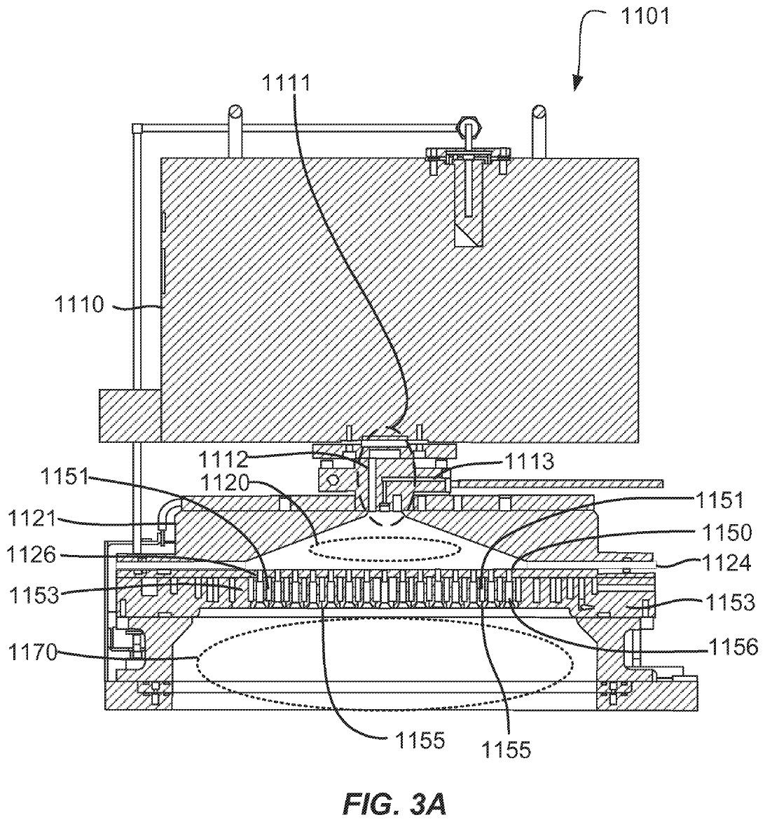

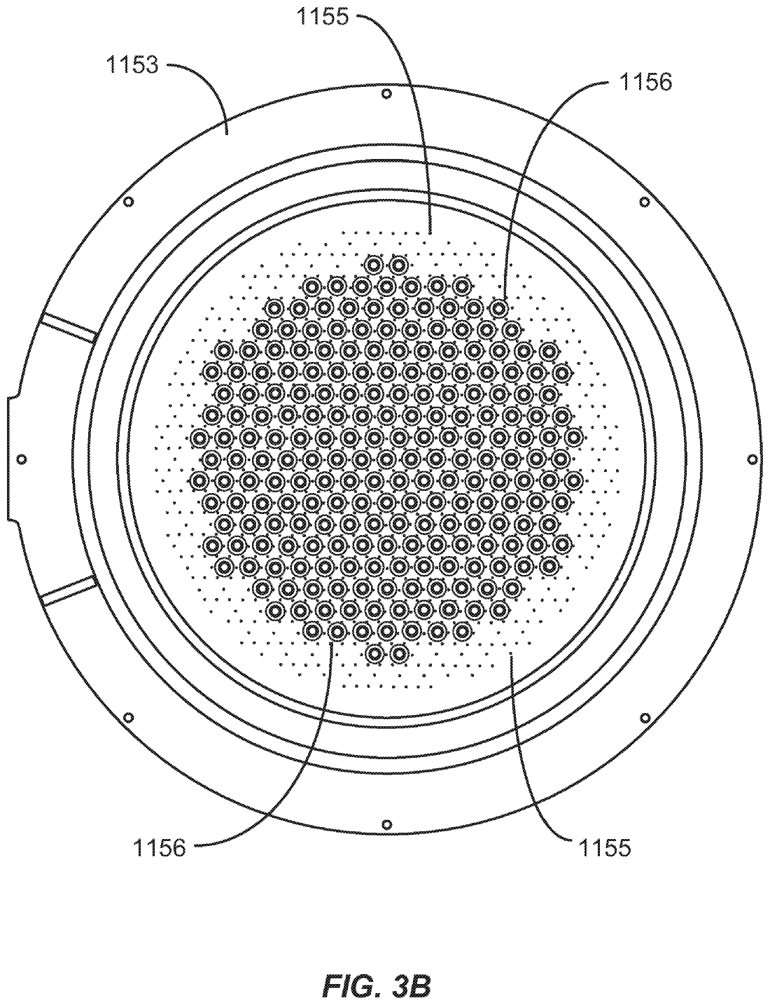

FIG. 3A is a substrate processing chamber 1101 according to disclosed embodiments. A remote plasma system (RPS) 1110 may process a gas which then travels through a gas inlet assembly 1111. Two distinct gas supply channels are visible within the gas inlet assembly 1111. A first channel 1112 carries a gas that passes through the remote plasma system (RPS) 1110, while a second channel 1113 bypasses the RPS 1110. The first channel 1112 may be used for the process gas and the second channel 1113 may be used for a treatment gas in disclosed embodiments. The lid (or conductive top portion) 1121 and a showerhead 1153 are shown with an insulating ring 1124 in between, which allows an AC potential to be applied to the lid 1121 relative to showerhead 1153. The process gas travels through first channel 1112 into chamber plasma region 1120 and may be excited by a plasma in chamber plasma region 1120 alone or in combination with RPS 1110. The combination of chamber plasma region 1120 and/or RPS 1110 may be referred to as a remote plasma system herein. The perforated partition (also referred to as a showerhead) 1153 separates chamber plasma region 1120 from a substrate processing region 1170 beneath showerhead 1153. Showerhead 1153 allows a plasma present in chamber plasma region 1120 to avoid directly exciting gases in substrate processing region 1170, while still allowing excited species to travel from chamber plasma region 1120 into substrate processing region 1170.

Showerhead 1153 is positioned between chamber plasma region 1120 and substrate processing region 1170 and allows plasma effluents (excited derivatives of precursors or other gases) created within chamber plasma region 1120 to pass through a plurality of through-holes 1156 that traverse the thickness of the plate. The showerhead 1153 also has one or more hollow volumes 1151 which can be filled with a precursor in the form of a vapor or gas (such as a silicon-free carbon-containing precursor) and pass through small holes 1155 into substrate processing region 1170 but not directly into chamber plasma region 1120. Showerhead 1153 is thicker than the length of the smallest diameter 1150 of the through-holes 1156 in this disclosed embodiment. In order to maintain a significant concentration of excited species penetrating from chamber plasma region 1120 to substrate processing region 1170, the length 1126 of the smallest diameter 1150 of the through-holes may be restricted by forming larger diameter portions of through-holes 1156 part way through the showerhead 1153. The length of the smallest diameter 1150 of the through-holes 1156 may be the same order of magnitude as the smallest diameter of the through-holes 1156 or less in disclosed embodiments.

In the embodiment shown, showerhead 1153 may distribute (via through-holes 1156) process gases which contain oxygen, hydrogen and/or nitrogen and/or plasma effluents of such process gases upon excitation by a plasma in chamber plasma region 1120. In embodiments, the process gas introduced into the RPS 1110 and/or chamber plasma region 1120 through first channel 1112 may contain one or more of NH₃, NₓH_{y} including N₂H₄, or a carrier gas such as helium, argon, nitrogen (N₂), etc. The second channel 1113 may also deliver a process gas and/or a carrier gas. Plasma effluents may include ionized or neutral derivatives of the process gas and may also be referred to herein as a radical precursor or even a radical-nitrogen precursor referring to the atomic constituents of the process gas introduced.

In embodiments, the number of through-holes 1156 may be between about 60 and about 2000. Through-holes 1156 may have a variety of shapes but are most easily made round. The smallest diameter 1150 of through-holes 1156 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 1155 used to introduce a gas into substrate processing region 1170 may be between about 100 and about 5000 or between about 500 and about 2000 in different embodiments. The diameter of the small holes 1155 may be between about 0.1 mm and about 2 mm.

FIG. 3B is a bottom view of a showerhead 1153 for use with a processing chamber according to disclosed embodiments. Showerhead 1153 corresponds with the showerhead shown in FIG. 3A. Through-holes 1156 are depicted with a larger inner-diameter (ID) on the bottom of showerhead 1153 and a smaller ID at the top. Small holes 1155 are distributed substantially evenly over the surface of the showerhead, even amongst the through-holes 1156 which helps to provide more even mixing than other embodiments described herein.

An exemplary film is created on a substrate supported by a pedestal (not shown) within substrate processing region 1170 when plasma effluents arriving through through-holes 1156 in showerhead 1153 combine with a carbon-containing precursor arriving through the small holes 1155 originating from hollow volumes 1151. Substrate processing region 1170 may be equipped to support a plasma. A mild plasma is present in substrate processing region 1170 during deposition when forming some carbon films while no plasma is present during the growth of other exemplary films in disclosed embodiments.

A plasma may be ignited either in chamber plasma region 1120 above showerhead 1153 or substrate processing region 1170 below showerhead 1153. A plasma is present in chamber plasma region 1120 to produce the radical precursor from an inflow of a process gas. An AC voltage typically in the radio frequency (RF) range is applied between the conductive top portion 1121 of the processing chamber and showerhead 1153 to ignite a plasma in chamber plasma region 1120 during deposition. An RF power supply generates a high RF frequency of 13.56 MHz but may also generate other frequencies alone or in combination with the 13.56 MHz frequency.

During deposition of the flowable film, the plasma power of some embodiments may be in a range of about 10 W to about 200 W, about 10 W to about 100 W, about 10 W to about 50 W, about 50 W to about 200 W, about 50 W to about 100 W, about 100 W to about 200 W. During the optional post deposition curing process, the plasma power is in a range of about 100 W to about 500 W, about 100 W to about 400 W, about 100 W to about 300 W, about 100 W to about 200 W, about 200 W to about 500 W, about 200 W to about 400 W, about 200 W to about 300 W, about 300 W to about 500 W, about 300 W to about 400 W, or about 400 W to about 500 W.

The top plasma may be left at low or no power when the bottom plasma in the substrate processing region 1170 is turned on during a deposition or to clean the interior surfaces bordering the substrate processing region 1170. A plasma in substrate processing region 1170 is ignited by applying an AC voltage between showerhead 1153 and the pedestal or bottom of the chamber. A cleaning gas may be introduced into substrate processing region 1170 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the deposition system. The system controller executes system control software, which is a computer program stored in a computer-readable medium. The medium may be a hard disk drive, or other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

The controller includes a central processing unit (CPU), a memory, and one or more support circuits utilized to control the process sequence and regulate the gas flows from the gas panel. The CPU may be of any form of a general-purpose computer processor that may be used in an industrial setting. The software routines can be stored in the memory, such as random access memory, read only memory, floppy, or hard disk drive, or other form of digital storage. The support circuit is conventionally coupled to the CPU and may include cache, clock circuits, input/output systems, power supplies, and the like.

The memory can include one or more of transitory memory (e.g., random access memory) and non-transitory memory (e.g., storage). The memory, or computer-readable medium, of the processor may be one or more of readily available memory such as random access memory (RAM), read-only memory (ROM), floppy disk, hard disk, or any other form of digital storage, local or remote. The memory can retain an instruction set that is operable by the processor to control parameters and components of the system.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

The controller of some embodiments is configured to interact with hardware to perform the programmed function. For example, the controller can be configured to control one or more valves, motors, actuators, power supplies, etc.

Referring to FIG. 1 at 112, the initially flowable carbon film may be optionally cured or solidified after deposition. In some embodiments, the flowable carbon film is cured after depositing into a substrate feature without a seam.

The flowable carbon film is cured by exposure to a second plasma. The second plasma is formed by the excitation of a second plasma gas. In some embodiments, the second plasma gas comprises one or more of H₂, Ar, He or N₂.

Some embodiments of the disclosure advantageously provide for the flowable film to be cured in the same chamber as the flowable carbon film was deposited, providing increased throughput as compared to a process involving different chambers. In some embodiments, the entire method (deposition and curing) is performed in a single chamber without breaking vacuum. In some embodiments, the substrate is maintained at about the same temperature while exposing the substrate to the reactive plasma (depositing the flowable carbon film) and the second plasma (curing the carbon film).

While some process parameters may stay the same between deposition and curing processes, others may be controlled separately between the two processes. For example, in some embodiments, the pressure of the process chamber during deposition may be maintained in a range of about 1 Torr to about 10 Torr during deposition but may be lowered to a range of about 3 mTorr to about 2 Torr during curing.

The plasma utilized during the cure process may be an inductively coupled plasma or a conductively coupled plasma. In some embodiments, the plasma power is in a range of about 100 W to about 500 W or a subrange thereof as discussed elsewhere. In some embodiments, the plasma frequency may be in a range of about 400 kHz to about 40 MHz.

Some embodiments of the disclosure provide methods for forming air gaps within substrate features using the flowable carbon films disclosed herein. As used in this regard an air gap is an intentional void created within a substrate feature.

In some embodiments, a flowable carbon film is deposited in a first portion of the feature by embodiments disclosed herein and an additional material is deposited on the flowable carbon film in a second portion of the feature. After deposition of the additional material, the flowable carbon film is removed. In some embodiments, the flowable carbon film may be removed by a UV treatment or by exposing the substrate to a plasma consisting essentially of oxygen. As used in this regard, a plasma consisting essentially of oxygen comprises excited oxygen species and ions, and may be produced from any suitable material (e.g, oxygen gas, ozone).

Similar to the deposition and cure processes, the process required for air gap formation may be integrated and performed in a single chamber without breaking vacuum. In some embodiments, the substrate is maintained at about the same temperature throughout the method of forming an air gap.

In some embodiments, the flowable film is cured as disclosed above. In some embodiments, the flowable carbon film is cured before deposition of the additional material. In some embodiments, the flowable carbon film is cured after deposition of the additional material. For embodiments in which the flowable film is cured, the air gap is formed by removing the cured film from the first portion of the feature.

The term “gap” is used throughout with no implication that the etched geometry has a large horizontal aspect ratio. Viewed from above the surface, trenches may appear circular, oval, polygonal, rectangular, or a variety of other shapes. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A flowable carbon film deposition method comprising:
providing a substrate to a substrate processing region of a processing chamber;
forming a reactive plasma comprising a carbon-containing precursor, the carbon-containing precursor comprising substantially no oxygen, the reactive plasma comprising substantially no oxygen; and
exposing the substrate to the reactive plasma to deposit a flowable carbon film on the substrate, the flowable carbon film comprising substantially no silicon nor oxygen.

2. The method of claim 1, wherein the substrate has a substrate surface having at least one feature thereon, the at least one feature extending a depth from the substrate surface to a bottom surface, the at least one feature having an opening width at the substrate surface defined by a first sidewall and a second sidewall, the flowable carbon film is deposited in the at least one feature, and the at least one feature has a ratio of the depth to the opening width of greater than or equal to about 10:1.

3. The method of claim 2, wherein the flowable carbon film deposited in the at least one feature has substantially no seam.

4. The method of claim 1, wherein the carbon-containing precursor consists essentially of propene, acetylene or methane.

5. The method of claim 1, wherein the carbon-containing precursor comprises four to twelve carbon atoms.

6. The method of claim 1, wherein the carbon-containing precursor comprises at least one unsaturated bond.

7. The method of claim 6, wherein the carbon-containing precursor comprises a vinyl functional group.

8. The method of claim 7, wherein the carbon-containing precursor is selected from the group consisting of ethene, propene, isobutylene, butadiene, and styrene.

9. The method of claim 6, wherein the unsaturated bond is a terminal unsaturated bond.

10. The method of claim 1, further comprising exposing the flowable carbon film to a second plasma to cure the flowable carbon film.

11. The method of claim 10, wherein the second plasma is produced by exciting a second plasma gas, the second plasma gas comprising H₂, Ar, He or N₂.

12. The method of claim 10, wherein the method is performed in a single chamber without breaking vacuum.

13. The method of claim 10, wherein the substrate is maintained at about the same temperature while exposing the substrate to the reactive plasma and the second plasma.

14. The method of claim 1, wherein the substrate is maintained at a temperature in a range of about −100° C. to about 100° C.

15. The method of claim 14, wherein the substrate is maintained at a temperature less than or equal to 25° C.

16. A flowable carbon film deposition method comprising:
providing a substrate to a substrate processing region of a processing chamber, the substrate having a substrate surface with at least one feature thereon, the at least one feature extending a depth from the substrate surface to a bottom surface, the at least one feature having an opening width at the substrate surface defined by a first sidewall and a second sidewall, the at least one feature having a ratio of the depth to the opening width of greater than or equal to about 10:1;
forming a first plasma within the substrate processing region, the first plasma comprising a carbon-containing precursor and a first plasma gas, the carbon-containing precursor comprising substantially no oxygen, the first plasma comprising substantially no oxygen,
exposing the substrate to the first plasma to deposit a flowable carbon film in the at least one feature, the flowable carbon film deposited in the at least one feature has substantially no seam, and the flowable carbon film comprising substantially no silicon nor oxygen; and
exposing the flowable carbon film to a second plasma to cure the flowable carbon film, the second plasma produced by exciting a second plasma gas,
wherein the method is performed in a single chamber without breaking vacuum, and the substrate is maintained at about the same temperature throughout the method.

17. A method of forming an air gap in a substrate feature, the method comprising:
providing a substrate to a substrate processing region of a processing chamber, the substrate having a substrate surface with at least one feature thereon, the at least one feature extending a depth from the substrate surface to a bottom surface, the at least one feature having an opening width at the substrate surface defined by a first sidewall and a second sidewall, the at least one feature having a ratio of the depth to the opening width of greater than or equal to about 10:1;
depositing a flowable carbon film in a first portion of the at least one feature by a process comprising:
exciting a carbon-containing precursor to form a plasma, the carbon-containing precursor comprising substantially no oxygen, the plasma comprising substantially no oxygen; and
exposing the substrate to the plasma to deposit a flowable carbon film in the at least one feature, the flowable carbon film deposited in the at least one feature has substantially no seam, and the flowable carbon film comprising substantially no silicon nor oxygen;
depositing a material on the flowable carbon film in a second portion of the at least one feature; and
removing the flowable carbon film from the first portion of the at least one feature to form an air gap in the first portion of the at least one feature.

18. The method of claim 17, wherein the flowable carbon film is removed by UV treatment or by exposing the substrate to a plasma consisting essentially of oxygen.

19. The method of claim 17, wherein the method is performed in a single chamber without breaking vacuum and the substrate is maintained at about the same temperature throughout the method.

20. The method of claim 17, further comprising exposing the flowable carbon film to a second plasma to cure the flowable carbon film, the second plasma produced by exciting a second plasma gas.
